(19) United States
(12) Patent Application Publication
(10) Pub. No.: US 2014/0138815 A1
(43) Pub. Date: May 22, 2014

(54) SERVER PROCESSING MODULE

(71) Applicant: NVIDIA CORPORATION, Santa Clara, CA (US)

(72) Inventor: Abraham F. Yee, Cupertino, CA (US)

(73) Assignee: NVIDIA CORPORATION, Santa Clara, CA (US)

(21) Appl. No.: 13/682,584

(22) Filed: Nov. 20, 2012

(51) Int. Cl. H01L 25/16; H01L 25/00

(52) U.S. Cl. CPC H01L 25/16; H01L 25/50
USPC 257/737; 438/107

(57) ABSTRACT

One embodiment of the present invention sets forth a processing module including an interposer and a plurality of processing nodes. The interposer includes a plurality of through substrate vias. Each processing node includes a processing unit die coupled directly to a top surface of the interposer with a first plurality of solder bump structures, a memory die coupled directly to the top surface of the interposer with a second plurality of solder bump structures, and a plurality of circuit elements electrically coupling the processing unit die and the memory die. The processing module further includes a plurality of electrical connections formed on a bottom surface of the interposer and electrically coupled to the plurality of processing nodes through the plurality of through substrate vias. The processing module further comprises a plurality of interconnecting circuit elements electrically interconnecting the plurality of processing nodes.

### BACKGROUND OF THE INVENTION

1. Field of the Invention

The present invention generally relates to integrated circuit packaging, and, more specifically, to processing module packaging.

2. Description of the Related Art

Integrated circuit (IC) fabrication is a multi-step sequence which includes processes such as patterning, deposition, etching, and metallization. Typically, in the final processing steps, the resulting IC die are separated and packaged. IC packaging serves several purposes, including providing an electrical interface with the die, providing a thermal medium through which heat may be removed from the die, and/or providing mechanical protection for the die during subsequent usage and handling.

One type of IC packaging technique is referred to as “flip chip” packaging. In flip chip packaging, after the metallization process is complete, solder bump structures (e.g., solder balls, pads, etc.) are deposited on the die, and the die is separated from the wafer (e.g., via dicing, cutting, etc.). The die is then inverted and positioned on a substrate so that the solder bumps align with electrical connections formed on the substrate. Heat is applied via a solder reflow process to re-melt the solder bumps and attach the die to the substrate. The die/substrate assembly may further be underfilled with a non-conductive adhesive to strengthen the mechanical connection between the die and the substrate.

Over the past decade, datacenters have experienced unprecedented growth as the popularity of Internet-related products and services has increased. However, as providers seek to further increase the processing and storage capacities of datacenters and servers, they confront many obstacles, including increased power consumption and thermal management requirements. Moreover, such datacenters may include tens of thousands of processors and memory devices, each of which must be provided with proper electrical connections and sufficient heat removal. Thus, as the scale of datacenters continues to increase, the complexity, size, and thermal requirements of server components is quickly becoming a limiting factor.

Accordingly, there is a need in the art for a more effective way of providing server component packaging.

### SUMMARY OF THE INVENTION

One embodiment of the present invention sets forth a processing module including an interposer and a plurality of processing nodes. The interposer includes a plurality of through substrate vias. Each processing node includes a processing unit die coupled directly to a top surface of the interposer with a first plurality of solder bump structures, a memory die coupled directly to the top surface of the interposer with a second plurality of solder bump structures, and a plurality of circuit elements electrically coupling the processing unit die and the memory die. The processing module further includes a plurality of electrical connections formed on a bottom surface of the interposer and electrically coupled to the plurality of processing nodes through the plurality of through substrate vias. The processing module further comprises a plurality of interconnecting circuit elements electrically interconnecting the plurality of processing nodes.

Further embodiments provide a method of fabricating a processing module.

One advantage of the disclosed technique is that a plurality of processing nodes may be disposed on a single interposer wafer, simplifying the fabrication and packaging processes, streamlining thermal management, and allowing a greater number of processing and memory die to be included in a smaller processing module.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram illustrating a processing system configured to implement one or more aspects of the present invention;

FIGS. 2A and 2B illustrate schematic views of a conventional processing module having a conventional configuration;

FIGS. 3A-3C illustrate schematic views of a processing module having aspects of the present invention;

FIGS. 4A and 4B illustrate schematic views of the processing module of

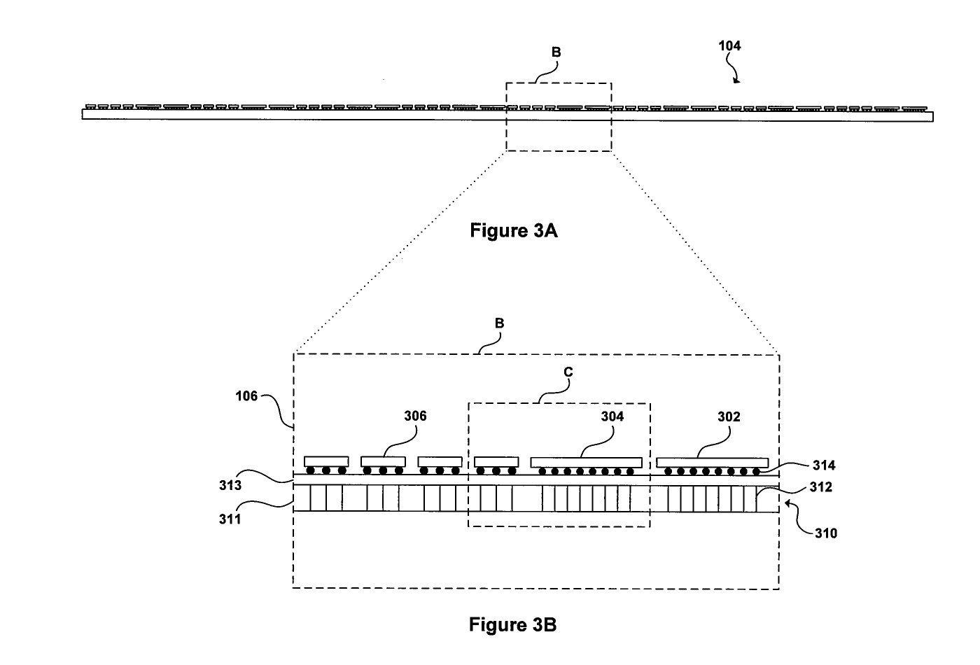

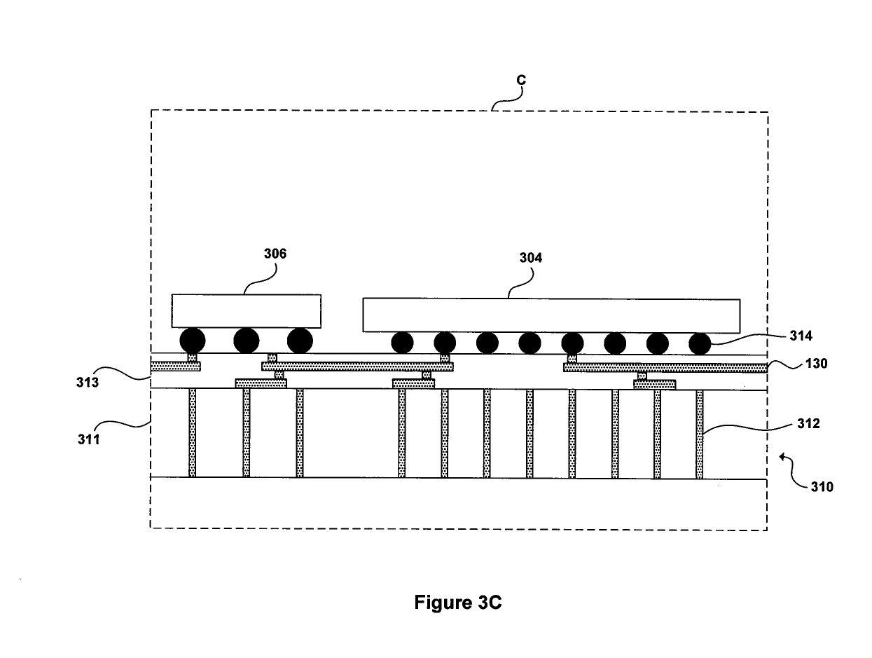

FIGS. 3A and 3B having aspects of the present invention;

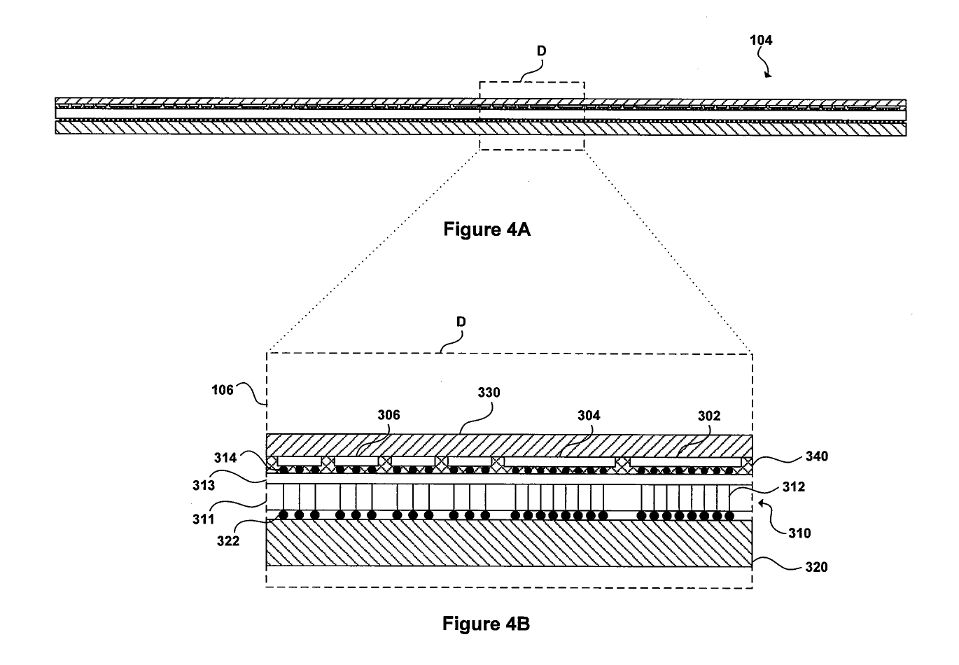

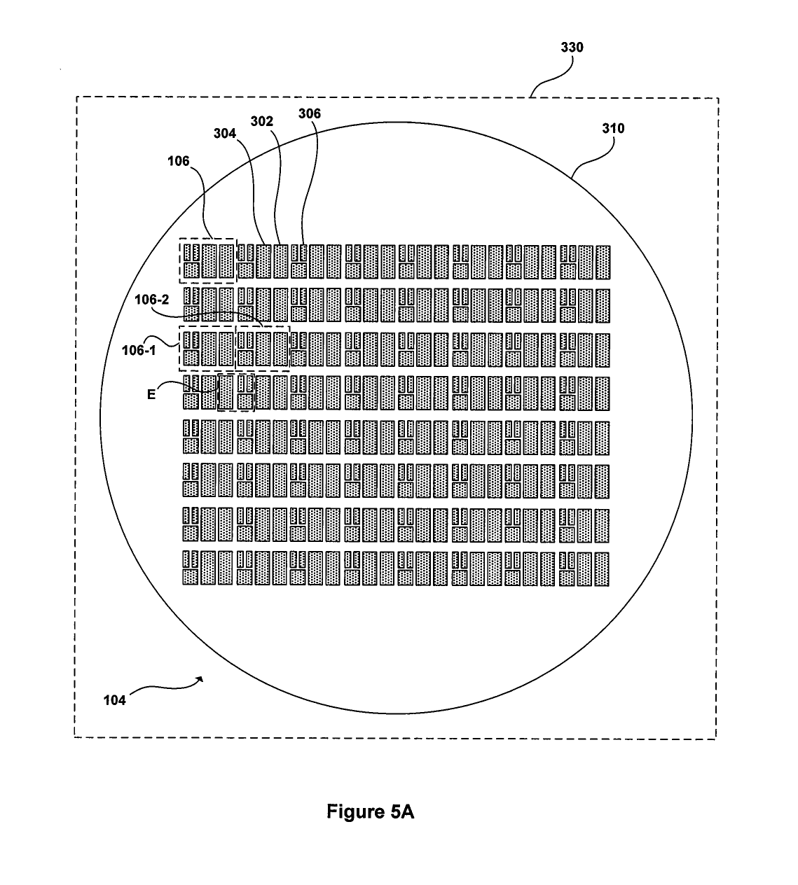

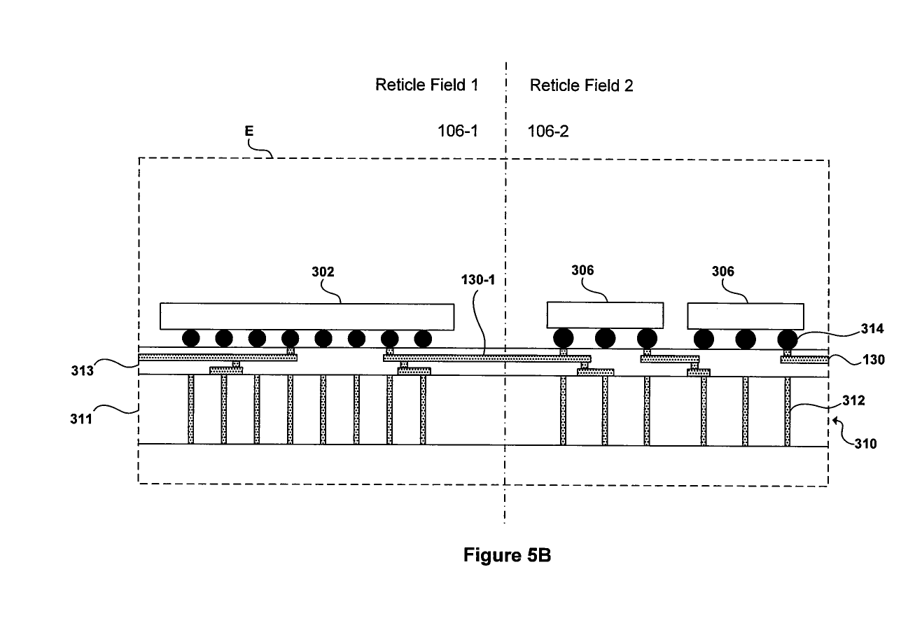

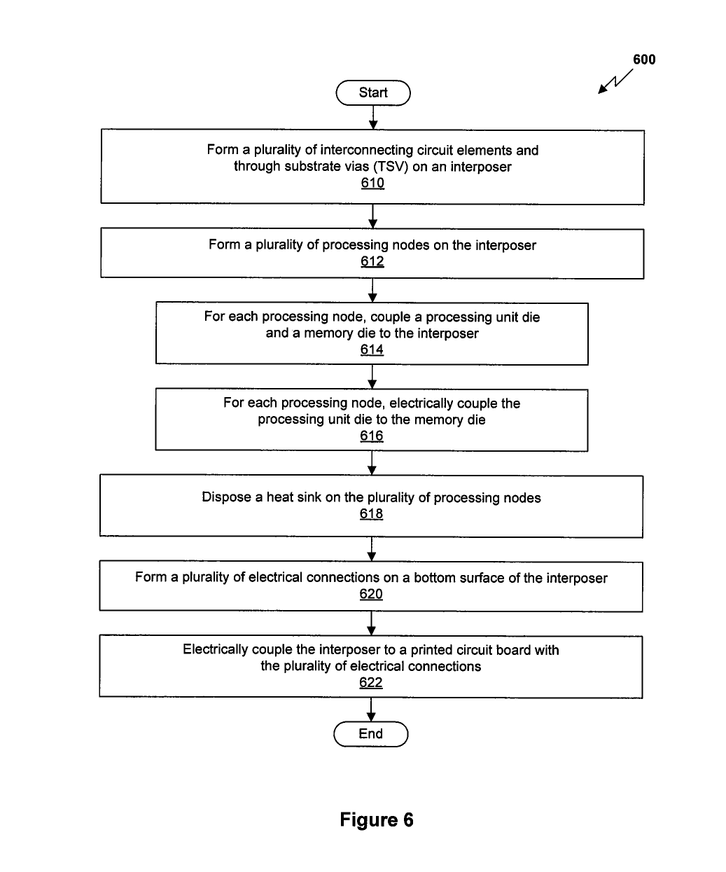

FIGS. 5A and 5B illustrate a schematic view of the interposer of the processing module of FIGS. 4A and 4B having aspects of the present invention; and

FIG. 6 is a flow diagram of methods steps for fabricating a processing module, according to one embodiment of the present invention.

### DETAILED DESCRIPTION

In the following description, numerous specific details are set forth to provide a more thorough understanding of the present invention. However, it will be apparent to one of skill in the art that the present invention may be practiced without one or more of these specific details.

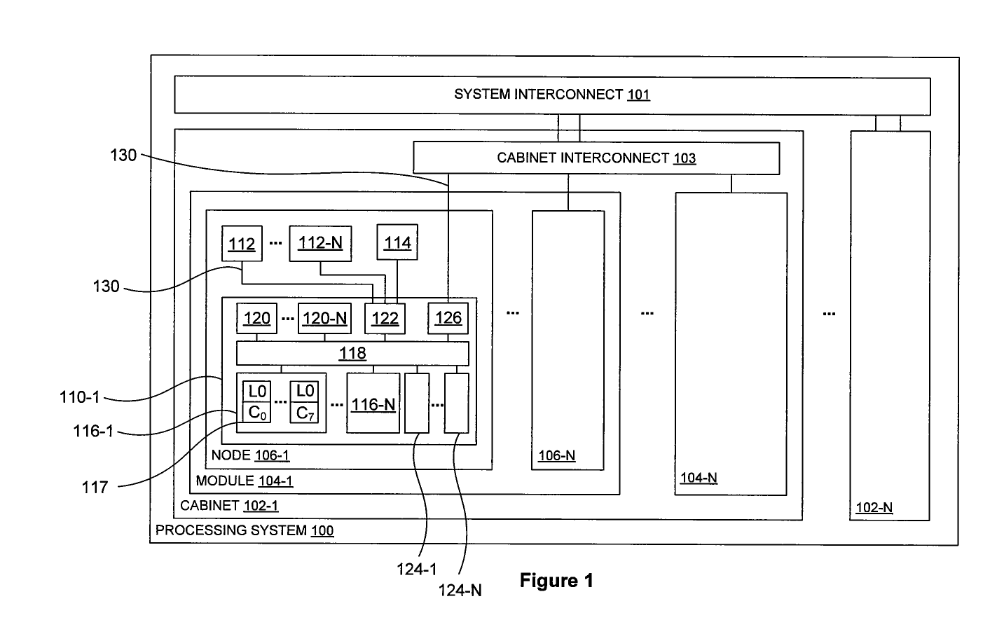

FIG. 1 is a block diagram illustrating a processing system 100 configured to implement one or more aspects of the present invention. Processing system 100 may include a plurality of cabinets 102 communicating via a system interconnect 101. Each cabinet 102 includes a plurality of processing modules 104. Each processing module 104 includes a plurality of processing nodes 106 communicating via a cabinet interconnect 103. Each processing node 106 includes a processing unit 110, a plurality of DRAM memory units 112, and a nonvolatile memory unit 114. Each processing unit 110 may include a plurality of streaming multiprocessors (SM) 116 having a plurality of processing cores 117.

A network-on-chip (NoC) controller 118 provides communication between the streaming multiprocessors 116 and cache memory 120 included in each processing unit 110 via circuit elements 130. Each processing unit 110 further communicates with the DRAM memory units 112 and the nonvolatile memory unit 114 via a memory controller 122. An addressing unit 124 selects streaming multiprocessors 116 for input/output operations. Finally, a network interface controller 126 provides communication between each processing node 106 and the cabinet interconnect 103.

The exemplary processing system 100 illustrated in FIG. 1 includes a cabinet 102 having 16 processing modules 104, each of which includes 8 processing nodes 106. Further, as illustrated, each processing node 106 includes a processing unit 110 having 256 streaming multiprocessors 116. However, in other embodiments, the processing system 100 may include any number of cabinets 102, processing modules 104, processing nodes 106, processing units 110, and streaming multiprocessors 116. For example, in another embodiment, each processing module 104 may include 32 processing nodes 106. In yet another embodiment, each processing module 104 may include 64 or more processing nodes 106.

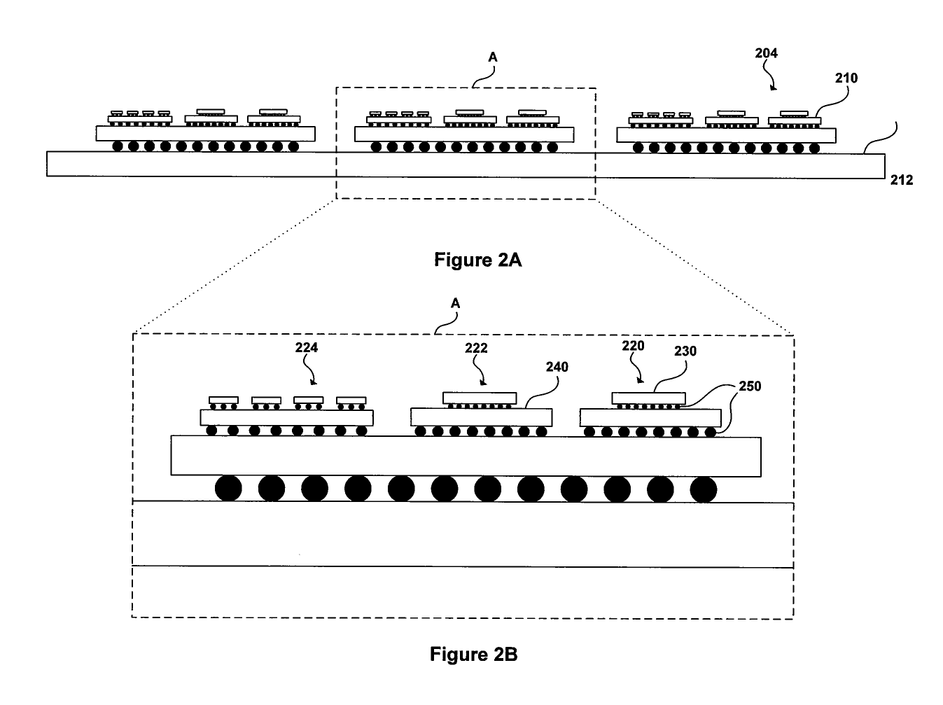

FIGS. 2A and 2B illustrate schematic views of a conventional processing module 204 having a conventional configuration. The processing module 204 includes a plurality of server boards 210, each of which are coupled to a printed circuit board (PCB) 212. Each server board 210 includes a central processing unit package 220, a graphics processing unit package 222, and a memory unit package 224. Each package 220, 222, 224 includes a die 230 coupled to an interposer 240 with a plurality of solder balls 250. Additionally, each server board 210 is coupled to the printed circuit board 212 with a plurality of solder balls 250.

FIGS. 3A-3C illustrate schematic views of a processing module 104 having aspects of the present invention. The processing module 104 includes a plurality of processing unit die 302, 304 and a plurality of memory die 306 mechanically and electrically coupled to an interposer 310 with a plurality of solder bump structures 314. The processing unit die 302, 304 may include any type of integrated circuit capable of processing data. In the exemplary embodiment illustrated in FIGS. 3A and 3B, the processing unit die 302, 304 include a central processing unit (CPU) die 302 and a graphics processing unit (GPU) die 304. In other embodiments, the processing unit die 302, 304 may include, for example, parallel computing die, system-on-chip (SoC) die, single-core processor die, multi-core processor die, and the like. Moreover, the processing unit die 302, 304 may be the same type of die, or they may be different types of die. In the exemplary embodiment, the memory die 306 include volatile memory die (e.g., dynamic random-access memory (DRAM) die, DRAM cubes, static random-access memory (SRAM), and the like). The memory die 306 may further include nonvolatile memory die (e.g., flash memory, magnetoresistive RAM, and the like).

The interposer 310 may comprise a silicon wafer having a silicon layer 311 and a redistribution layer 313 and having a thickness of approximately 10 μm to approximately 500 μm. In the exemplary embodiment illustrated in FIGS. 3A and 3B, the interposer 310 has a thickness of approximately 20 μm to approximately 100 μm. The interposer 310 may have any shape or diameter. For example, an interposer 310 having a diameter of 100 mm, 200 mm, 300 mm, 450 mm, etc. may be used. A plurality of through substrate vias (TSV) 312 may be disposed in the interposer 310 to provide electrical connections between the top surface of the interposer 310, upon which the processing unit die 302, 304 and memory die 306 are disposed, and the bottom surface of the interposer 310.

Each of the processing unit die 302, 304 and memory die 306 may be coupled to the top surface of the interposer 310 with a plurality of solder bump structures 314. The solder bump structures 314 may include, for example, solder balls, solder pads, or any other type of structures capable of mechanically and/or electrically coupling integrated circuit die to the interposer 310. The solder bump structures 314 may be attached directly to the processing unit die 302, 304 or memory die 306, or the solder bump structures 314 may couple to under bump metallurgy (UBM) pads disposed on the die. Further, the solder bump structures 314 may couple the processing unit die 302, 304 and memory die 306 directly to the through substrate vias 312, or the processing unit die 302, 304 and memory die 306 may be indirectly coupled to the through substrate vias 312 with intermediate circuit elements 130, as described below with respect to FIG. 3C.

As shown in FIG. 3C, the redistribution layer 313 may include a plurality of circuit elements 130 for interconnecting the processing unit die 302, 304, memory die 306, and through substrate vias 312. The redistribution layer 313 may comprise an oxide, such as silicon dioxide (SiO₂). The circuit elements 130 may comprise a conductive material, such as copper or aluminum. Circuit elements 130 may be deposited on multiple levels within the redistribution layer 313 to provide connections between components within each processing node 106. Additionally, circuit elements 130 deposited on or within the redistribution layer 313 may form connections between (i.e., interconnect) two or more different processing nodes 106, as described in further detail with respect to FIGS. 5A and 5B.

FIGS. 4A and 4B illustrate schematic views of the processing module 104 of FIGS. 3A and 3B having aspects of the present invention. The processing module 104 illustrated in FIGS. 4A and 4B further includes a heat sink 330 mounted to the back surface of the processing unit die 302, 304. Additionally, the heat sink 330 may be mounted to the back surface of the memory die 306.

Prior to mounting the heat sink 330, the processing unit die 302, 304 and/or memory die 306 may be underfilled and/or overmolded with a thermoset material 340, such as an epoxy, resin, or the like, to strengthen the mechanical coupling between the die and the interposer 310. After overmolding, excess material may be removed (e.g., via grinding, chemical mechanical polishing (CMP), etc.) to expose the back surfaces of the processing unit die 302, 304 and/or memory die 306. The heat sink 330 then may be mounted to the processing unit die 302, 304 and/or memory die 306, for example, by disposing a thermal interface material (TIM) on a surface between the die 302, 304, 306 and the heat sink 330.

The heat sink 330 may comprise any thermally conductive material, including metals such as copper, aluminum, and silver. Additionally, although the exemplary heat sink 330 illustrated in FIGS. 4A and 4B includes a rectangular geometry, the heat sink 330 may have any geometry capable of removing heat from the processing module 104. For example, the heat sink 330 may include heat pipes or conduit through which a cooling fluid (e.g., air, water, coolant, etc.) may flow. In other embodiments, the heat sink 330 may include a plurality of fins in order to increase the surface area of the heat sink 330. In still other embodiments, the heat sink may be monolithic, or the heat sink may be fabricated from multiple components.

Once the heat sink 330 has been mounted, the heat sink 330 may be used as a carrier during subsequent process steps. For example, the heat sink 330 may serve as a carrier by which to handle the interposer 310 when thinning the interposer 310 to expose the through substrate vias 312. After exposing the through substrate vias 312, electrical connections 322 may be disposed on the bottom surface of the interposer 310. In the exemplary embodiment illustrated in FIGS. 4A and 4B, the electrical connections 322 include a ball grid array (BGA) configuration. However, any type of electrical connections capable of providing an electrical interface to the interposer 310 may be used. Other types of electrical connections include pin grid arrays (PGA), land grid arrays (LGA), and the like.

After disposing electrical connections 322 on the bottom surface of the interposer 310, the interposer 310 and heat sink 330 assembly may be disposed on a printed circuit board (PCB) 320. The printed circuit board 320 may include various electrical components such as decoupling capacitors, power amplifiers, power regulators, rack interconnects, and other types of electrical or optical interconnects for providing communications or electrical power to the processing unit die 302, 304 and/or memory die 306. Further, the printed circuit board 320 may provide electrical connections between processing unit die 302, 304 and/or connections between different processing nodes 106, processing modules 104, and/or cabinets 102.

FIGS. 5A and 5B illustrate a schematic view of the interposer 310 of the processing module 104 of FIGS. 4A and 4B having aspects of the present invention. The interposer 310 includes a plurality of processing nodes 106. More specifically, the exemplary embodiment illustrated in FIG. 5 includes 64 processing nodes 106. The processing nodes 106 may be electrically interconnected or “stitched” together such that the processing nodes 106 form one (or more) interconnected element(s).

As discussed with respect to FIGS. 3A-3C, the interposer 310 may include a silicon layer 311 and a redistribution layer 313. As such, prior to coupling the processing unit die 302, 304 and memory die 306 to the top surface of the interposer 310, through substrate vias 312 and circuit elements 130 may be fabricated on and/or within the silicon layer 311 and/or redistribution layer 313 of the interposer 310. Fabrication of through substrate vias 312 and circuit elements 130 may include photolithography, etching, and metallization process steps.

In the exemplary embodiment provided herein, circuit elements 130 for 64 processing nodes 106, each having dimensions of approximately 26×32 mm, are fabricated on the interposer 310. The circuit elements 130 for each of the 64 processing nodes 106 may be fabricated by performing photolithography with the same reticle, or the circuit elements 130 may be fabricated using more than one reticle. For example, as shown in FIG. 5A, a first reticle may be used to fabricate circuit elements 130 for a first processing node 106-1, and a second reticle may be used to fabricate circuit elements 130 for a second processing node 106-2. The first and second reticles used to fabricate circuit elements 130 for the first and second processing nodes 106-1, 106-2 may have matching border patterns, enabling electrical interconnects to be formed between the first processing node 106-1 and the second processing node 106-2, as shown in FIG. 5B.

FIG. 5B illustrates a cross-sectional view of the first processing node 106-1 and the second processing node 106-2. As discussed above, circuit elements 130 for the first processing node 106-1 may be fabricated with a first reticle, and circuit elements 130 for the second processing node 106-2 may be fabricated with a second reticle. Advantageously, by using two or more different reticles to fabricate the circuit elements for the 64 processing nodes 106 illustrated in this exemplary embodiment, the processing nodes 106 may be interconnected with each other to form a single, interconnected processing element. For example, circuit element 130-1 illustrates an exemplary interconnection between the adjacent processing nodes 106-1, 106-2. Such circuit elements 130-1 may be fabricated with reticles having matching border patterns. Additionally, interconnecting circuit elements 130-1 may be fabricated with a reticle which is specifically configured to provide interconnections between (or “stitch”) two or more processing nodes 106. In still other embodiments, a single reticle having symmetrical border patterns—which enable the patterning of interconnecting circuit elements 130-1 for interconnecting multiple processing nodes 106—may be used. Although FIG. 5B illustrates an interconnecting circuit element 130-1 provided between adjacent processing nodes 106, it is further contemplated that interconnections may be provided between processing nodes 106 which are not adjacent, but which are separated by one or more intervening processing nodes 106.

Although this exemplary processing module 104 includes 64 processing nodes 106, any number of processing nodes (e.g., 16, 32, 128, or more) may be included in each processing module 104. Each processing node 106 includes processing unit die 302, 304 and memory die 306. Moreover, each processing node 106 may include the same type(s) of processing unit die 302, 304 and memory die 306, or each processing node 106 may include different types of processing unit die 302, 304 and memory die 306. For example, one or more processing nodes 106 may include a plurality of central processing unit die, while one or more other processing nodes 106 may include a plurality of graphics processing unit die. Furthermore, although two processing unit die 302, 304 are illustrated with respect to the exemplary embodiment described herein, each processing node 106 may include any number of processing unit die. Similarly, any number of memory die 306 and any number of other types of integrated circuit die may be included in each processing node 106. Additionally, circuit elements 130 for processing nodes 106 having larger or smaller sizes than those described with respect to the exemplary embodiment may be fabricated. Once the circuit elements 130 and through substrate vias 312 have been fabricated, the interposer 310 may be cut into an appropriate shape and size (e.g., a rectangle, square, etc.)

FIG. 6 is a flow diagram of methods steps for fabricating a server processing module, according to one embodiment of the present invention. Although the method steps are described in conjunction with the exemplary embodiments illustrated in FIGS. 1, 3A-3C, 4A, 4B, 5A and 5B, persons skilled in the art will understand that the method steps may be performed, in any order, for the fabrication, manufacturing, or processing of other devices within the scope of the present invention.

The method begins at step 610, where a plurality of circuit elements 130 (e.g., interconnecting circuit elements 130-1) and a plurality of through substrate vias 312 are formed on the interposer 310. As discussed above with respect to FIG. 5, fabrication of the through substrate vias 312 and circuit elements 130 may include photolithography, etching, and metallization process steps. At step 612, a plurality of processing nodes 106 are formed on a top surface of the interposer 310. At step 614, for each processing node 106, a processing unit die 302, 304 and a memory die 306 is coupled to the top surface of the interposer 310. At step 616, each processing unit die 302, 304 is electrically coupled to a memory die 306. For example, each memory die 306 may be coupled to the top surface of the interposer 310 with a plurality of solder bump structures 314 such that each of the memory die 306 is electrically coupled to at least one of the plurality of processing unit die 302, 304 through one or more of the plurality of circuit elements 130.

Each processing unit die 302, 304 and/or memory die 306 may be directly coupled to the top surface of the interposer 310, or the processing unit die 302, 304 and/or memory die 306 may be coupled via an intermediate layer or structure which does not substantially affect the footprint of the processing unit die 302, 304 and memory die 306. The processing unit die 302, 304 and memory die 306 may be overmolded with a thermoset material and/or a thermal interface material. Excess overmolding material 340 may be removed via a grinding or polishing process.

Next, at step 618, a heat sink 330 may be disposed on the plurality of processing nodes 106. The heat sink 330 may contact a back surface of each processing unit die 302, 304 and/or memory die 306. Additionally, a thermal interface material may be disposed between the heat sink 330 and the processing unit die 302, 304 and/or memory die 306.

At step 620, a plurality of electrical connections 322 may be formed on a bottom surface of the interposer 310. The plurality of electrical connections 322 may electrically couple to one or more of the plurality of processing nodes 106 through the plurality of through substrate vias 312. Forming the plurality of electrical connections 322 may include thinning the bottom surface of the interposer 310. Further, forming the plurality of electrical connections 322 may include disposing ball grid array, pin grid array, or land grid array structures on the bottom surface of the interposer 310. Finally, at step 622, the interposer is electrically coupled to a printed circuit board (PCB) 320 via the plurality of electrical connections 322.

In sum, a plurality of integrated circuit (IC) die (e.g., central processing unit(s), graphics processing unit(s), memory structure(s), and/or the like) may be mounted on an interposer, such as a semiconductor wafer. The interposer may provide electrical connections between the plurality of die disposed on its surface. Additionally, the server interposer may include through-substrate vias for providing electrical connections to the circuit board on which the interposer is mounted. Finally, the backsides of the plurality of die may be covered with a thermally conductive and electrically insulating material, and a heat sink and/or carrier may be mounted on the backside of the die.

One advantage of the disclosed technique is that a plurality of processing nodes may be disposed on a single interposer wafer, simplifying the fabrication and packaging processes, streamlining thermal management, and allowing a greater number of processing and memory die to be included in a smaller processing module.

The invention has been described above with reference to specific embodiments. Persons of ordinary skill in the art, however, will understand that various modifications and changes may be made thereto without departing from the broader spirit and scope of the invention as set forth in the appended claims. The foregoing description and drawings are, accordingly, to be regarded in an illustrative rather than a restrictive sense.

Therefore, the scope of embodiments of the present invention is set forth in the claims that follow.

What is claimed:

1. A processing module comprising:
an interposer comprising a plurality of through substrate vias;
a plurality of processing nodes, each processing node comprising:
a processing unit die coupled directly to a top surface of the interposer with a first plurality of solder bump structures;
a memory die coupled directly to the top surface of the interposer with a second plurality of solder bump structures; and
a plurality of circuit elements electrically coupling the processing unit die and the memory die;
a plurality of electrical connections formed on a bottom surface of the interposer and electrically coupled to the plurality of processing nodes through the plurality of through substrate vias; and
a plurality of interconnecting circuit elements electrically interconnecting the plurality of processing nodes.

2. The processing module of claim 1, wherein each processing unit die comprises a plurality of processing cores and a memory controller.

3. The processing module of claim 1, wherein the plurality of processing nodes comprises at least 16 interconnected processing nodes.

4. The processing module of claim 1, wherein the plurality of processing nodes comprise a first processing node type fabricated with a first reticle and a second processing node type fabricated with a second reticle.

5. The processing module of claim 1, further comprising a heat sink disposed on the plurality of processing nodes.

6. The processing module of claim 1, wherein each processing node further comprises a plurality of memory die comprising one or more volatile memory die and one or more nonvolatile memory die.

7. The processing module of claim 1, wherein the plurality of electrical connections comprise at least one of a ball grid array, a land grid array, and a pin grid array.

8. The processing module of claim 1, further comprising a printed circuit board, wherein the plurality of electrical connections provide an electrical interface between the plurality of processing nodes and the printed circuit board.

9. The processing module of claim 8, wherein the printed circuit board supplies electrical power to the plurality of processing nodes and provides electrical communication between the plurality of processing nodes.

10. A method of fabricating a server processing module comprising:
forming a plurality of interconnecting circuit elements and a plurality of through substrate vias on an interposer;
forming a plurality of processing nodes on the interposer, each processing node formed by:
coupling a processing unit die directly to a top surface of the interposer with a first plurality of solder bump structures;
coupling a memory die directly to the top surface of the interposer with a second plurality of solder bump structures; and
electrically connecting the processing unit die and the memory die; and
forming a plurality of electrical connections on a bottom surface of the interposer,
wherein the plurality of electrical connections are electrically coupled to the plurality of processing nodes through the plurality of through substrate vias, and
the plurality of interconnecting circuit elements are configured to electrically interconnect the plurality of processing nodes.

11. The method of claim 10, wherein each processing unit die comprises a plurality of processing cores and a memory controller

12. The method of claim 10, wherein forming a plurality of processing nodes on the interposer comprises forming at least 16 interconnected processing nodes on the interposer.

13. The method of claim 10, wherein forming a plurality of processing nodes on the interposer comprises:
forming a first processing node type with a first reticle; and
forming a second processing node type with a second reticle,
wherein the first reticle and the second reticle are configured to fabricate the plurality of interconnecting circuit elements electrically interconnecting the first processing node type and the second processing node type.

14. The method of claim 10, further comprising disposing a heat sink on the plurality of processing nodes.

15. The method of claim 10, wherein forming the plurality of electrical connections comprises thinning the bottom surface of the interposer.

16. The method of claim 10, further comprising overmolding the plurality of processing nodes prior to disposing a heat sink on the plurality of processing nodes.

17. The method of claim 10, wherein forming each processing node further comprises coupling a plurality of memory die to the interposer, the plurality of memory die comprising one or more volatile memory die and one or more nonvolatile memory die.

18. The method of claim 10, wherein the plurality of electrical connections comprise at least one of a ball grid array, a land grid array, and a pin grid array.

19. The method of claim 10, further comprising electrically coupling the interposer to a printed circuit board with the plurality of electrical connections.

20. The method of claim 19, further comprising:
supplying electrical power from the printed circuit board to the plurality of processing nodes; and
providing electrical communication between the plurality of processing nodes via the printed circuit board.
